(19) United States
(12) Patent Application Publication
(10) Pub. No.: US 2008/0001298 A1
(43) Pub. Date: Jan. 3, 2008

(54) SEMICONDUCTOR DEVICE AND METHOD OF FABRICATING THE SAME

(75) Inventors: Shuichi Nakamura, Kawabe (JP); Jota Fukuhara, Yokkaichi (JP); Tomio Katata, Yokkaichi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/769,167

(22) Filed: Jun. 27, 2007

(30) Foreign Application Priority Data
Jun. 28, 2006 (JP) 2006-178061

(51) Int. Cl. H01L 23/528; H01L 21/4763

(52) U.S. Cl. 257/774; 438/640; 257/E23.151; 257/E21.495

(57) ABSTRACT

A semiconductor device includes a first conductive layer including a first upper surface, an insulating layer formed on the first conductive layer and having a hole which is adjacent to the first conductive layer and penetrating the insulating layer, the hole having an upper part and a lower part, a second conductive layer formed along an inner surface of the lower part of the hole and in electrical contact with the first conductive layer, and a third conductive layer formed in an inner surface of the upper part of the hole and inside the second conductive layer in the lower part of the hole and in electrical contact with the second conductive layer.

### CROSS-REFERENCE TO RELATED APPLICATIONS

This application is based upon and claims the benefit of priority from the prior Japanese Patent Application No. 2006-178061 filed on Jun. 28, 2006, the entire contents of which are incorporated herein by reference.

### BACKGROUND OF THE INVENTION

1. Field of the Invention

The present invention relates to a semiconductor device having an insulating layer structure provided on a conductive layer and a method of fabricating the same.

2. Description of the Related Art

U.S. Pat. No. 6,423,626 discloses a technique for forming an insulating layer on an electrically conductive layer and a hole in the insulating layer. A conductive layer is formed in the hole so that electrical connection is provided between these conductive layers. According to the disclosed technique, a contact hole is formed in the insulating layer and a titanium layer is formed in the contact hole. When the contact hole has a lip where a titanium layer is formed into a cusped shape, the cusped part of the titanium layer is at least partially removed by a chemical mechanical polish (CMP) process. Subsequently, other conductive layers (titanium nitride (TiN) layer and metal layer) are formed in the contact hole.

However, as shown in FIGS. 6 and 7 of the aforementioned U.S. patent, in the case where the conductive layers are formed into the cusped shape even slightly inside the contact hole relative to the lip, void occurs in the contact hole when other conductive layers are subsequently formed. In this case, the inventors confirmed that the void resulted in high resistance of other conductive layers. In order that this problem may be overcome, it is conceived that a film thickness for the planarization should be increased when the titanium layer is planarized by the CMP process, so that the whole titanium layer formed into the cusped shape inside the contact hole is removed.

Recently, however, the reduction in the diameter of the contact hole has become conspicuous with refinement of semiconductor devices and reduction in the design rules. Under these circumstances, a film thickness of an insulating film needs to be set so as to be equal to or above a predetermined value in order that the insulating layer may be maintained at a predetermined insulation performance. Almost the whole titanium layer formed into a pointed shape can be removed when the technique disclosed by the aforesaid U.S. patent is employed to increase the film thickness for planarization. However, the insulating layer cannot be formed so as to have a desired film thickness and maintained at a predetermined insulation performance. Accordingly, since the contact hole needs to be processed under a high aspect ratio, it is difficult to employ the structure and process disclosed by the aforesaid U.S. patent in point of practical utility.

### BRIEF SUMMARY OF THE INVENTION

Therefore, an object of the present invention is to provide a semiconductor device which is configured so as to prevent occurrence of void in the conductive layers in the contact holes thereby to suppress high resistivity of the conductive layers.

In one aspect, the present invention provides a semiconductor device comprising a first conductive layer including a first upper surface, an insulating layer formed on the first upper surface of the first conductive layer and including a second upper surface and a hole having an upper part and a lower part, the hole penetrating the insulating layer from the second upper surface of the insulating layer to the first upper surface of the first conductive layer, a second conductive layer formed along an inner surface of the lower part of the hole and electrically contacting with the first conductive layer, including a third upper surface located between the first and the second upper surfaces and an inner recess having a bottom portion located between the first and the third upper surfaces, and a third conductive layer formed in the upper part of the hole and electrically contacting with the second conductive layer, the third conductive layer including a first portion located in the upper part and a second portion located in the recess of the second conductive layer.

In another aspect, the invention provides a method of fabricating a semiconductor device comprising forming a first insulating layer on a first conductive layer, the first insulating layer having an upper surface, the first conductive layer including an upper part; forming a first hole which is adjacent to the upper part of the first conductive layer and extends through the first insulating layer, the first hole having an upper opening; depositing a second conductive layer on the first insulating layer formed with the first hole so that the upper opening of the first hole is constricted by the second conductive layer, and simultaneously forming the second conductive layer along an inner surface of the first hole while a space is defined in the first hole; planarizing the second conductive layer until the upper surface of the first insulating layer is reached; forming a second insulating layer on the second conductive layer and the first insulating layer; forming a second hole in the second insulating layer and simultaneously, removing an upper part of the second conductive layer so that the constricted upper opening of the first hole is enlarged; and burying a third conductive layer inside the second conductive layer through the upper opening of the second hole.

### BRIEF DESCRIPTION OF THE DRAWINGS

Other objects, features and advantages of the present invention will become clear upon reviewing the following description of the preferred embodiment with reference to the accompanying drawings in which:

FIG. 1 is a longitudinal section of a multilayer wiring structure in the semiconductor device of one embodiment in accordance with the present invention; and

FIGS. 2 to 11 are longitudinal sections of the multilayer wiring structure in sequential steps of the fabricating process.

### DETAILED DESCRIPTION OF THE INVENTION

One embodiment of the present invention will be described with reference to the accompanying drawings. In the embodiment, the invention is applied to a semiconductor device 1 comprising a p-type silicon substrate 2 serving as a semiconductor substrate and a multilayer wiring structure 3 formed on the silicon substrate 2.

### Structure

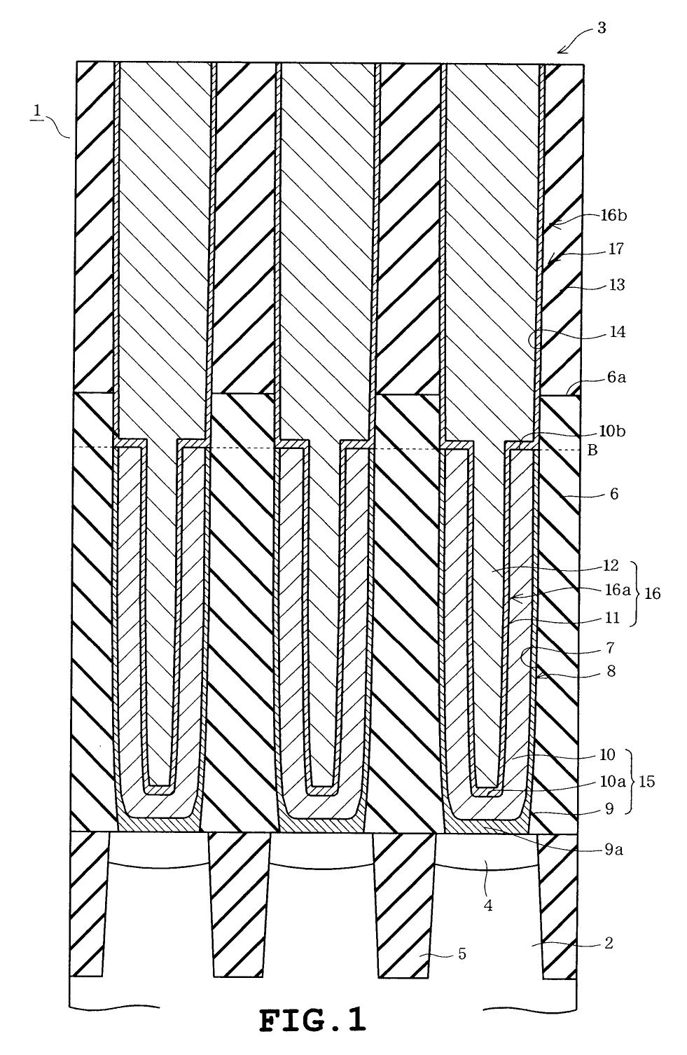

Referring to FIG. 1, a plurality of n-type diffusion layers (diffusion region) 4 are provided in a surface layer of the silicon substrate 2 so as to be disposed in parallel with each other (juxtaposed) in one axial direction in the surface of the silicon substrate 2. Contact regions (not shown) are provided at the surface layer side of the respective diffusion layers 4. The multilayer wiring structure 3 including two (a plurality of) layers are formed on the contact regions. The diffusion layers 4 are insulated by element isolation films 5 buried between a plurality of adjacent diffusion layers 4. Each diffusion layer 4 is used as a source/drain region of a transistor (not shown).

The multilayer wiring structure 3 is configured as follows. A first interlayer insulating film 6 (serving as a first insulating layer) is formed on the silicon substrate 2. The first interlayer insulating film 6 is a film stack made from tetraethyl orthosilicate (TEOS) and boro-phospho-silicate glass (BPSG). TEOS and BPSG have film thicknesses of 300 nm and 400 nm respectively, for example. The first interlayer insulating film 6 is formed on first upper surfaces of the diffusion layers 4

The first interlayer insulating film 6 has a plurality of contact holes 7 (serving as a first hole and a lower part of the hole) communicating with upper parts of the diffusion layers 4 at the surface layer side of the silicon substrate 2. Each contact hole 7 is formed so as to have a larger diameter at a vertically central part thereof than at vertical ends thereof, or in other words, each contact hole 7 is formed into the shape of a barrel. The diameter of each contact hole 7 is set at a value ranging from 70 to 80 nm, for example. Contact plugs 8 (a first plug) are buried in the contact holes 7 respectively. The contact plugs 8 are in electrical contact with the diffusion layers 4 respectively as shown in FIG. 1. The contact plugs 8 have substantially the same diameter (several tens nm) and disposed in parallel with each other (juxtaposed) in the axial direction in the surface of the silicon substrate 2 at predetermined intervals (several tens nm).

Each contact plug 8 includes a first barrier metal film 9 formed along an inner surface of the contact hole 7 and the surface of the silicon substrate 2, a first metal film (a first metal portion) 10 formed along an inner surface of the first barrier metal film 9, a second barrier metal film 11 formed along an inner surface of the first metal film 10 and a second metal film (a second metal portion) 12 formed inside the barrier metal film 11. Accordingly, when observing a transverse section of the contact plug 8 formed in each contact hole 7, it is understood that the first barrier metal film 9, first metal layer 10, second barrier metal film 11, second metal layer 12, second barrier metal film 11, first metal layer 10 and first barrier metal film 9 are formed sequentially in this order.

The first barrier metal film 9 is composed of a laminated structure of titanium (Ti) and titanium nitride (TiN), for example. Since the first barrier metal film 9 is formed by a sputtering process, for example, the film 9 is formed as a thin film on sidewalls in each contact hole 7, and a bottom part 9a in contact with the silicon substrate 2 has a larger film thickness than the sidewalls. When the first barrier metal film 9 is composed of the laminated structure of titanium (Ti) and titanium nitride (TiN), titanium and titanium nitride have film thicknesses of 6 nm and 4 nm respectively.

The first metal layer 10 is composed of tungsten. The first metal layer 10 is formed so as to have a film thickness of 20 nm along the inner surface of the first barrier metal 9. The second interlayer insulating film 13 is formed on the upper surface 6a of the first interlayer insulating film 6. The second interlayer insulating film 13 is made from nitride oxide silicon (SiON), for example and has a film thickness of 420 nm, for example. The second hole 14 serving as an upper hole part is formed in the second interlayer insulating film 13 so as to be located over the contact hole 7. The second interlayer insulating film 13 is formed as an upper part of the second hole 14 and located on the contact holes 7. The second hole 14 is formed so as to extend from the top of the second interlayer insulating film 13 to the first metal layer 10 and the top of the first barrier metal film 9 in the direction of the lower most part of the film 13.

Each hole 17 includes a contact hole 7 and a second hole 14 and is formed so as to extend vertically through the first and second interlayer insulating films 6 and 13. The second barrier metal film 11 is formed along an inner surface of the second hole 14, and the second metal layer 12 is formed on the inside of the second barrier metal film 11. The second barrier metal film 11 is made from titanium nitride (TiN), for example. Since the second barrier metal film 11 is formed from over the second interlayer insulating film by the sputtering process, for example, the second barrier metal film 11 is formed to be thinner than the inner wall surface of the first metal layer 10, and a part of the film 11 formed on a recess (bottom) 10a of the metal layer 10 constituting a lowermost part thereof has a larger film thickness than a film formed along the inner wall surface of the first metal layer 10.

The second metal layer 12 is made from tungsten, for example and buried inside the second hole 14 with a film width ranging from about 50 to about 60 nm without any void. The second metal layer 12 is formed on the inside of the second barrier metal film 11 in each contact hole 7. A second conductive layer 15 comprises the first barrier metal film 9 and the first metal layer 10. The second conductive layer 15 is in electrical contact with the diffusion layers 4. A third conductive layer 16 comprises the second barrier metal film 11 and the second metal layer 12. The third conductive layer 16 is in electrical contact with the second conductive layer 15.

The first barrier metal film 9 is formed along an inner surface of each contact hole 7, and the first metal layer 10 is formed along an inner surface of the first barrier metal film 9. An area inside first metal layer 10 is susceptible to void and/or seam. In particular, influences of such void and/or seam is noticeable when each contact hole 7 has a barreled shape.

In the above-described structure of the embodiment, the third conductive layer 16 is formed inside the second conductive layer 15 in each contact hole 7. Accordingly, void can be buried even when produced inside the second conductive layer 15 formed along the inner surface of each contact hole 7 during formation of the second conductive layer 15. Consequently, high resistivity of each of the second and third conductive layers 15 and 16 can be suppressed and accordingly, the resistance value of each conductive layer can be reduced.

### Fabricating Method

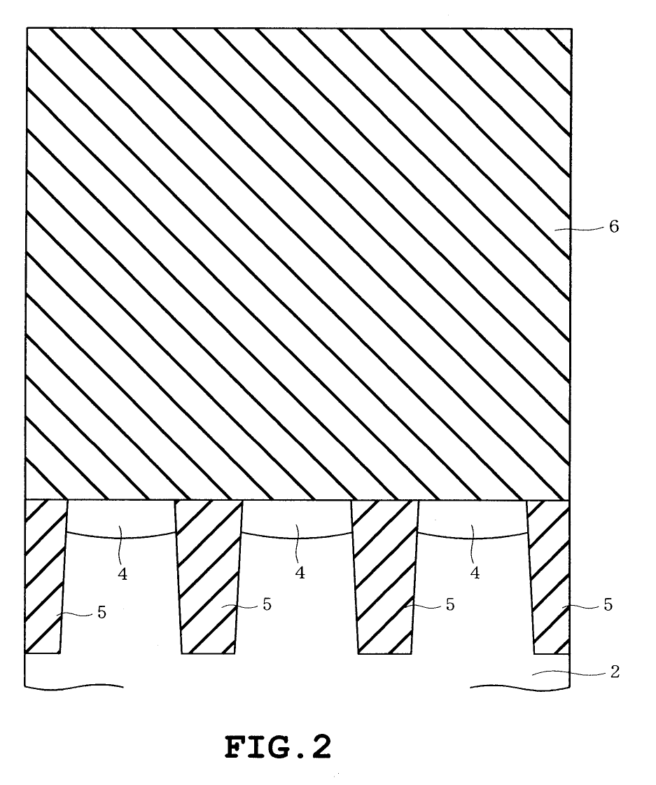

A method of fabricating the foregoing structure will be described with reference to FIGS. 2 to 11. Since one of the features of the fabricating method resides in a method of a multilayer wiring structure 3 having a plurality of layers, detailed description will be eliminated regarding the diffusion layers 4 formed in the surface layer of the silicon substrate 2 and the element isolation region (the element isolation film 5) of the STI structure. The method of fabricating the structure on the silicon substrate 2 will be described in the following. Some of the steps in the following fabrication method may be eliminated or some steps may be added to the fabricating method if the invention can be realized.

Referring to FIG. 2, the first interlayer insulating film 6 serving as the first insulating film is formed on the silicon substrate 2. The first interlayer insulating film 6 is formed by laminating oxide films such as TEOS and silicade glass such as BPSG by a high density plasma chemical vapor deposition (HDP-CVD) process so as to have film thicknesses of 300 nm and 400 nm respectively.

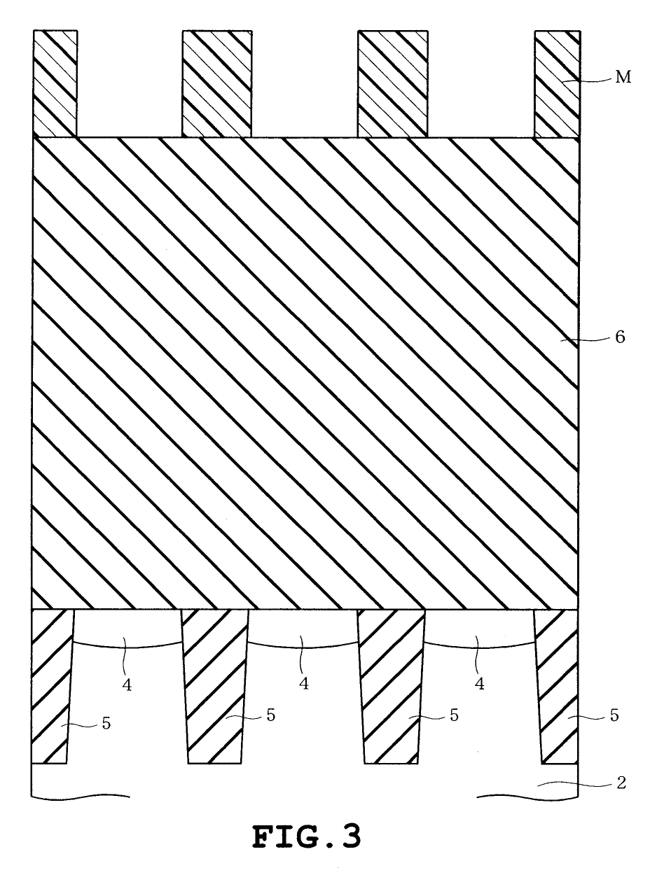

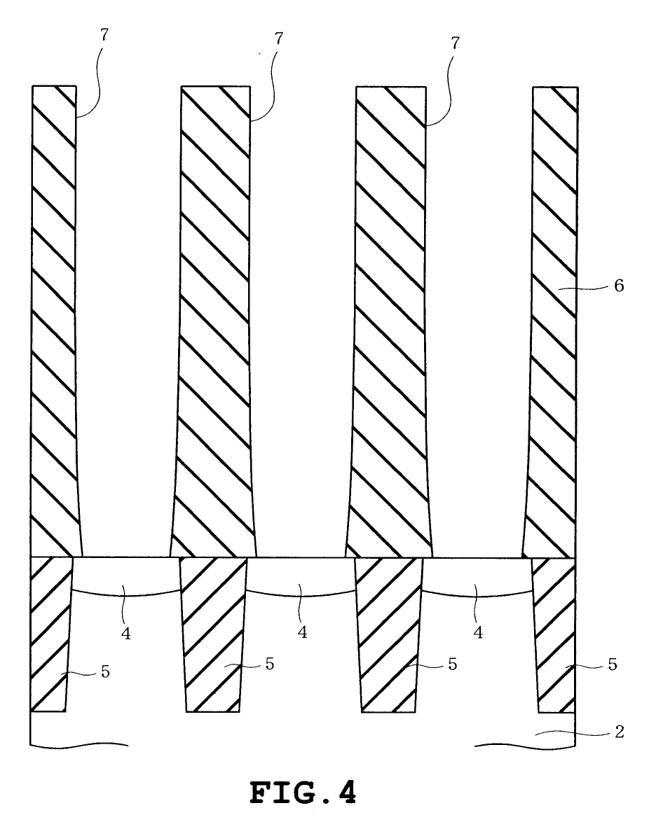

Resist is then applied to the first interlayer insulating film 6 and patterned thereby to be formed into a mask pattern M, as shown in FIG. 3. Subsequently, as shown in FIG. 4, the contact holes 7 are formed through the first interlayer insulating film 6 by a reactive ion etching (RIE) process so that the contact holes 7 penetrate an upper part of each diffusion layer 4. The mask pattern M is removed by ashing. Each contact hole 7 is formed so as to be tapered downward or so as to have the shape of barrel (the diameter of the vertically central part is larger than that of the other part) and the diameter of each contact hole 7 is gradually reduced toward vertical ends thereof.

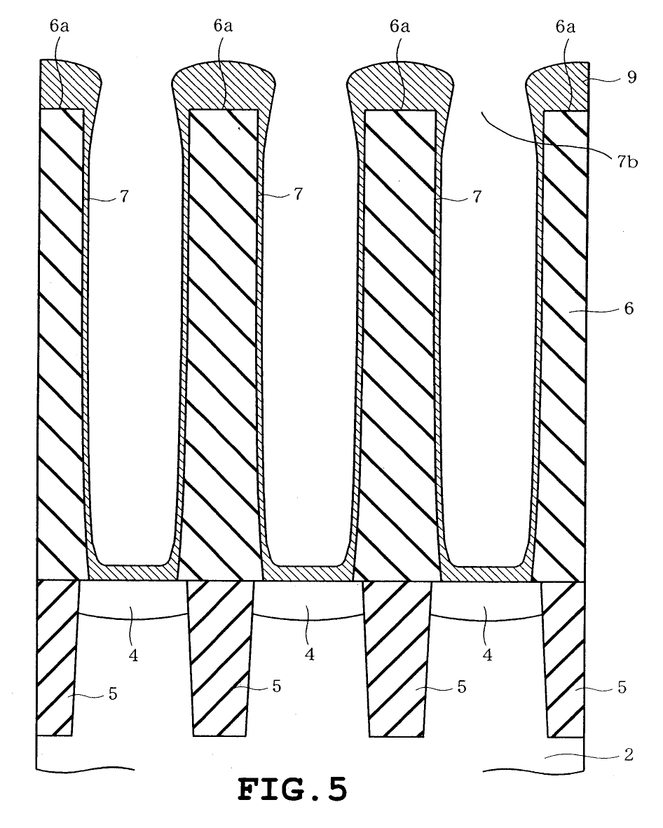

Subsequently, the titanium film is formed on the inner surface of each contact hole 7 by the sputtering process and thereafter, a titanium nitride (TiN) film is formed by the sputtering process, whereby the first barrier metal film 9 is formed along the inner surface of each contact hole 7, as shown in FIG. 5. In this case, when the sputtering process is carried out from over the silicon substrate 2, titanium is deposited thick particularly on the first interlayer insulating film 6, whereby the first barrier metal film 9 is formed into an overhanging shape relative to each contact hole 7. As a result, an upper opening 7b of each contact hole 7 is constricted.

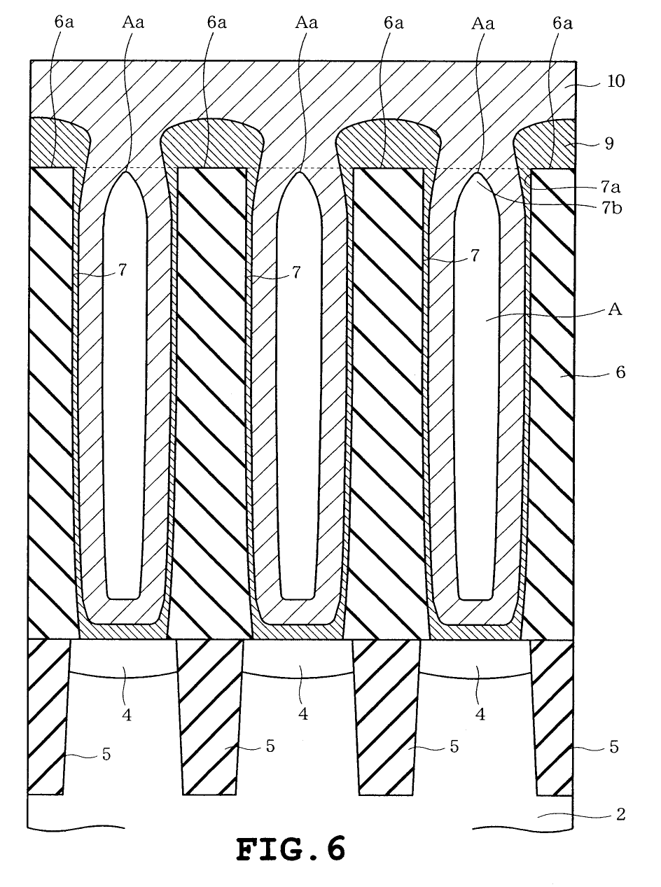

Subsequently, as shown in FIG. 6, the first metal layer 10 such as tungsten is deposited about 300 nm to 400 nm from over the first barrier metal film 9 and each contact hole 7. Consequently, the aforesaid depositing process can form the first metal layer 10 with a film thickness of about 20 nm on the side of each contact hole 7. The CVD process is usually employed to bury the first metal layer 10 in each contact hole 7. However, with progress in element refinement, the first metal layer 10 is firstly formed by an atomic layer deposition (ALD) process. The first metal layer 10 is grown by atomic layer deposition by the ALD process, and the first metal layer 10 is further formed by a normal CVD process. As a result, the upper opening 7b of each contact hole 7 constricted by the first barrier metal film 9 is further constricted thereby to be closed as shown in FIG. 6. Consequently, void A is formed which is entirely covered with the first metal layer 10. The void A has an upper end Aa which tends to be located lower as the film formed on the upper wall surface 7a of each contact hole 7 has a large thickness. In the embodiment, the upper end Aa of the void A is located lower than an upper surface 6a of the first interlayer insulating film 6.

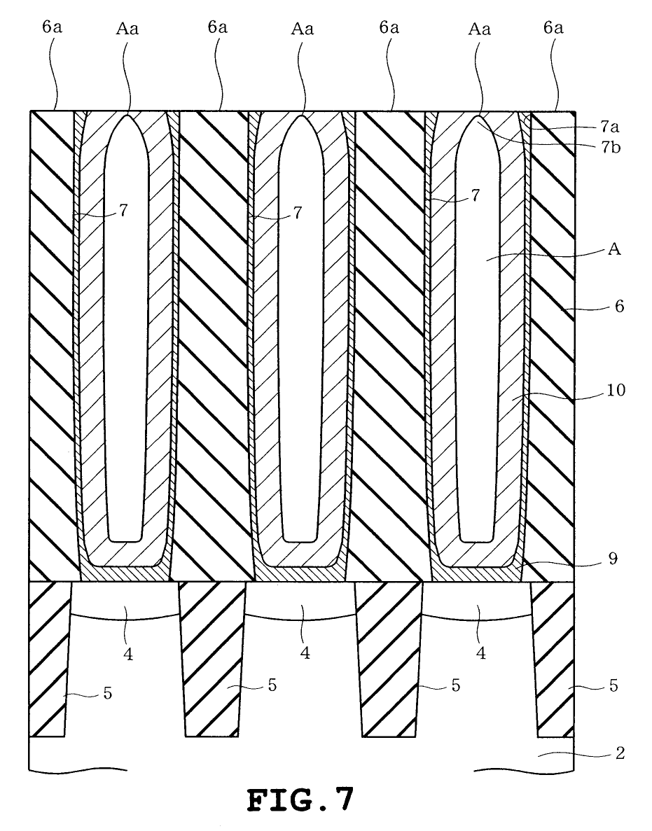

Subsequently, as shown in FIG. 7, the first metal layer 10 and the first barrier metal film 9 are planarized up to the upper surface 6a of the first interlayer insulating film 6 by the CMP process, for example. As the result of the planarization process, the first interlayer insulating film 6 can be maintained at a uniform film thickness, and the insulating performance of the first interlayer insulating film 6 can be retained. The upper end Aa of the void A is still covered by the first metal layer 10 even after execution of the planarization process, whereupon the upper end Aa of the void A remains closed.

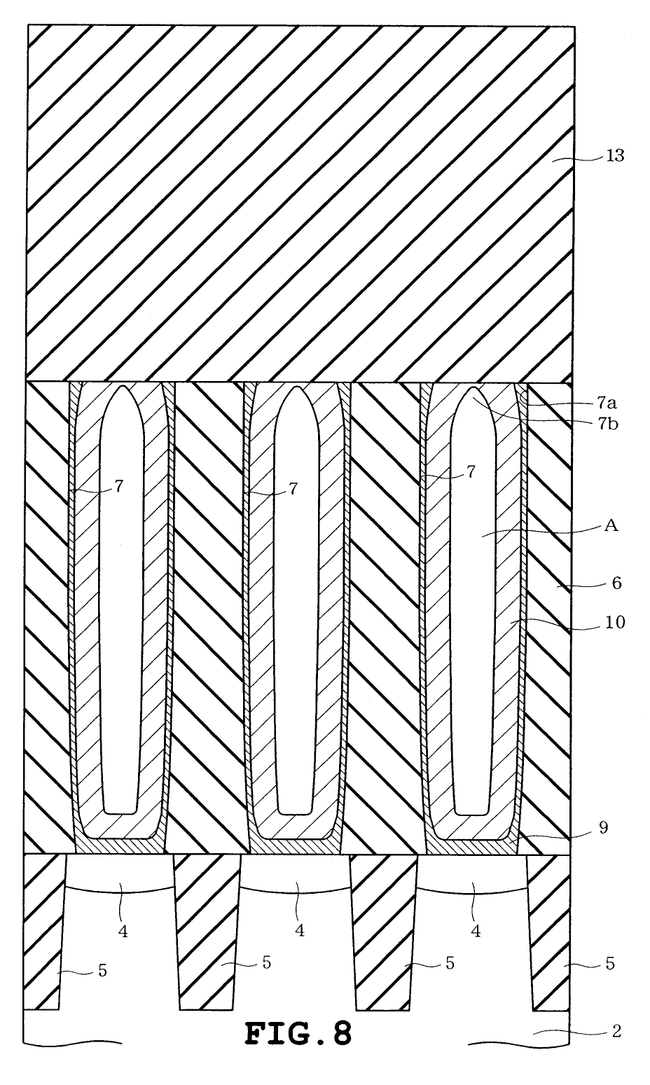

Subsequently, as shown in FIG. 8, the second interlayer insulating film 13 with a film thickness of 420 nm, for example, is deposited on the planarized first metal layer 10 and the first barrier metal film 9 by the plasma CVD process (the HDP-CVD process, for example). The second interlayer insulating film 13 is made from silicon nitride and oxide, for example. In this case, since the upper end Aa of void A is covered with the first metal layer 10 thereby to be closed, the material of the second interlayer insulating film 13 can be prevented from being buried in the void A.

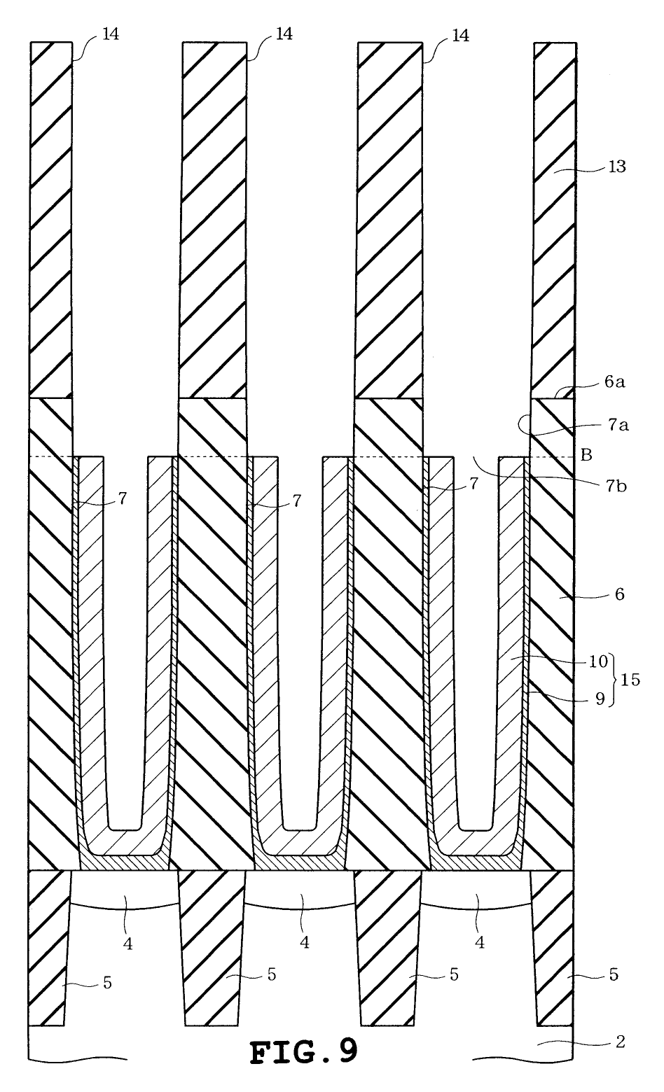

Subsequently, as shown in FIG. 9, the second holes 14 are formed through the second interlayer insulating film 13. In this case, an anisotropic etching process is carried out by an RIE method employing, for example, a CF₄/O₂ mixed gas in which CF₄ has a higher mixture ratio. This etching condition facilitates removal of the titanium film/titanium nitride film composing the first barrier and tungsten composing the first metal layer 10 as well as removal of the second interlayer insulating film 13. The anisotropic etching process is carried out under this condition so that an upper part of the second conductive layer 15 (the first barrier metal film 9 and the first metal layer 10) simultaneously with the forming of the second holes 14. The upper parts of first barrier metal film 9 and first metal layer 10 are removed to a position 50 nm downward from the upper surface of the first interlayer insulating film 6 (see broken line B in FIG. 9), whereby the upper end Aa of void A is opened and the closed upper openings 7b are re-opened.

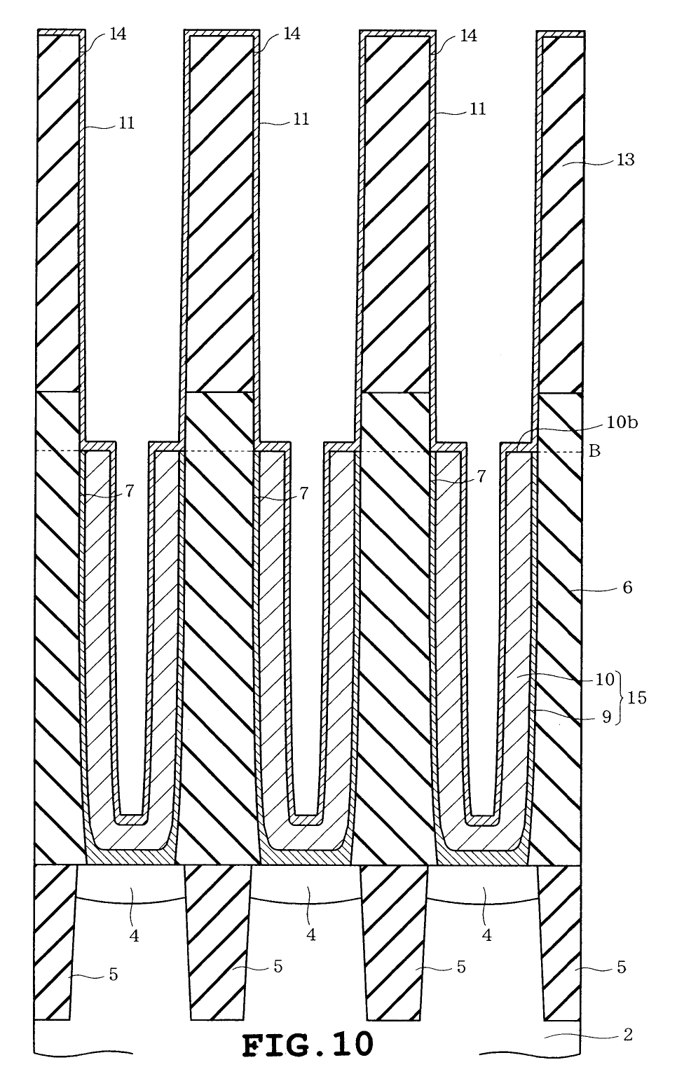

Subsequently, as shown in FIG. 10, the second barrier metal films 11 each of which has a film thickness of about 10 nm are formed on the inner surfaces of second holes 14 by a sputtering method using titanium nitride (TiN). In this case, the second barrier metal films 11 are also formed on the upper surfaces 10b and inner surfaces of the first metal layers 10 exposed as the result of opening the void A.

No titanium film is necessitated when the second barrier metal film 11 is formed in the void A. The reason for this is that the third conductive layers 16 are contactless with the silicon substrate 2. When formed into a film by the sputtering method, titanium is easy to deposit on the upper walls of the second holes 14. In the above case, however, since no titanium needs to be formed into a film, titanium can be prevented from being formed on the upper walls of the second holes 14.

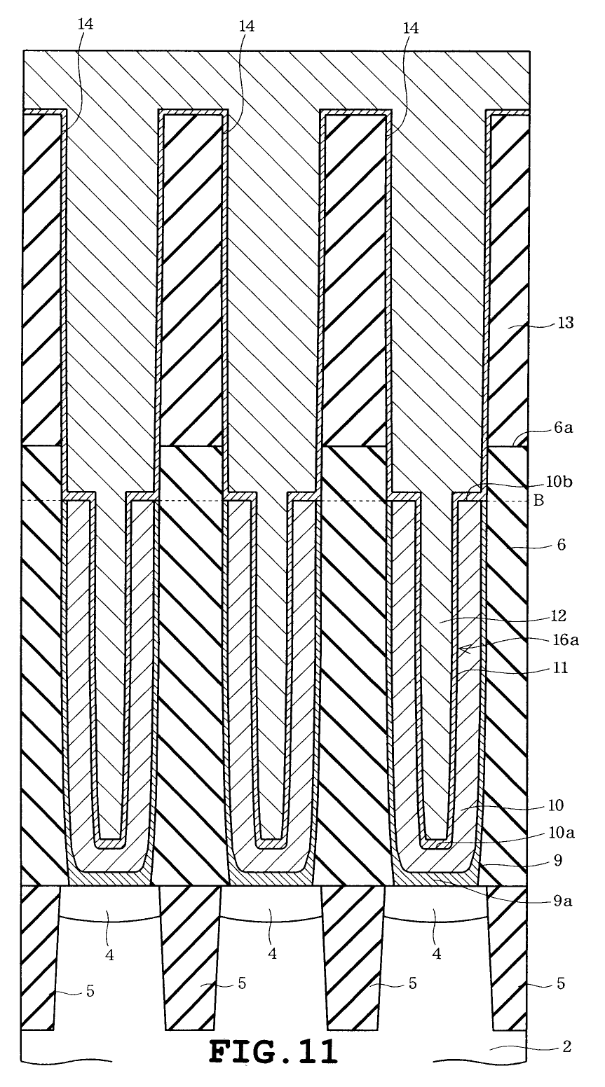

Subsequently, as shown in FIG. 11, the second metal layers 12 are buried inside the second barrier metal films 11 by the CVD process. Each second metal layer 12 is comprised of tungsten, for example. In this case, the second metal layer 12 is made by substantially the same method as that in the case where the first metal layer 10 is buried. As a result, no void is formed in the second holes 14 since the second barrier metal film 11 is not thick formed on the upper walls of the second holes 14.

Subsequently, as shown in FIG. 1, the second metal layers 12 and the second barrier metal layers 11 are removed by the planarization process. Thereafter, upper wiring layers (not shown) are formed on the second barrier metal layers 11 and the second metal layers 12 although the forming of the upper wiring layers is not shown. The multilayer wiring structure 3 can be configured as described above.

In the foregoing method, the second holes 14 are formed through the second interlayer insulating film 13 and simultaneously, the upper parts of the second conductive layers 15 formed inside the first interlayer insulating film 6 are removed such that the upper ends Aa of the closed voids A are re-opened. The third conductive layers 16 are buried inside the second conductive layers 15 from above the upper openings 7b of the respective contact holes 7. Consequently, the semiconductor device can be configured so that formation of void can be prevented inside the second conductive layers 15 buried in the respective contact holes 7, whereupon high resistivity of the second and third conductive layers 15 and 16 can be suppressed.

The first metal layers 10 and the first barrier metal layers 9 are planarized until the upper surface 6a of the first interlayer insulating film 6 is reached. The second interlayer insulating film 13 is formed on the upper surface 6a and the anisotropic etching process is carried out so that the second holes 14 are formed through the second interlayer insulating film 13 and simultaneously, the upper parts of the first metal layers 10 and first barrier metal films 9 are removed so that the upper ends of the closed voids A closed are re-opened. The second barrier metal films 11 and second metal layers 12 are formed inside the respective first metal layers 10 from above the upper openings 7b. Consequently, the semiconductor device can be configured so that formation of void can be prevented inside the second conductive layers 15 buried in the respective contact holes 7, whereupon high resistivity of the second and third conductive layers 15 and 16 can be suppressed.

When the first barrier metal films 9 are formed on the contact regions (not shown), the titanium films are formed by the sputtering process and thereafter, the titanium nitride film is formed by the sputtering process. Subsequently, the second interlayer insulating films 13 are removed so that the second holes 14 are formed and the first barrier metal films 9 are simultaneously removed. Accordingly, the first barrier metal film 9 can be removed in synchronism with the second interlayer insulating film 13 even when a film thickness of a part of the first barrier metal film 9 corresponding to the upper sidewall 7a of the contact hole 7 is larger than a film thickness of a lower part of the first barrier metal film 9 as the result of use of titanium. Consequently, the fabricating process can be simplified since a separate step of removing the first barrier metal film 9 is not necessitated.

In forming the second holes 14, the anisotropic etching is carried out under the condition where the CF₄/O₂ mixed gas in which CF₄ has a higher mixture ratio is used. Consequently, the first barrier metal film 9 comprised of titanium, titanium nitride or the like can easily be removed. Since the first metal layer 10 or the second metal layer 12 is comprised of tungsten, the burying characteristic can be improved.

The invention should not be limited by the description of the foregoing embodiment but the embodiment may be modified or expanded as follows:

The invention is applied to the multilayer wiring structure 3 provided with the contact plug formed on the silicon substrate 2 in the foregoing embodiment. However, the invention may be applied to a multilayer wiring structure for electrically connecting a plurality of wiring layers.

The diffusion layer 4 (diffusion region) formed at the surface layer side of the silicon substrate 2 serves as the first conductive layer in the foregoing embodiment. However, any conductive layer (any metal, for example) may serve as the first conductive layer.

The second conductive layer 15 comprises the first barrier metal film 9 and the first metal layer 10 in the foregoing embodiment. The third conductive layer 16 comprises the second barrier metal film 11 and the second metal layer 12. However, the composition may also be applied to the polyplug as well as to the metal plug.

Although the first and second metal layers 10 and 12 are made from tungsten in the foregoing embodiment, the layers may be made from another material such as tungsten nitride, copper, aluminum or the like.

The planarization process is carried out until the parts of the layer 10 and film 9 located near the upper end of the void A are exposed. The second interlayer insulating film 13 is formed while the upper openings 7b are kept closed. However, the upper openings 7b may or may not be closed in the case where the upper openings 7b are open and the insulating film 13 is not formed in the void of each contact hole 7 at the time the second interlayer insulating film 13 is formed.

The invention may be applied to any type of semiconductor device with the multilayer wiring structure 3.

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a first conductive layer including a first upper surface;
an insulating layer formed on the first upper surface of the first conductive layer and including a second upper surface and a hole having an upper part and a lower part, the hole penetrating the insulating layer from the second upper surface of the insulating layer to the first upper surface of the first conductive layer;
a second conductive layer formed along an inner surface of the lower part of the hole and electrically contacting with the first conductive layer, including a third upper surface located between the first and the second upper surfaces and an inner recess having a bottom portion located between the first and the third upper surfaces; and
a third conductive layer formed in the upper part of the hole and electrically contacting with the second conductive layer, the third conductive layer including a first portion located in the upper part and a second portion located in the recess of the second conductive layer.

2. The semiconductor device according to claim 1, wherein the lower part of the hole is formed into a barreled shape.

3. The semiconductor device according to claim 1, wherein the second conductive layer includes a first metal portion and a first barrier metal film formed on the first metal portion.

4. The semiconductor device according to claim 3, wherein the third conductive layer includes a second metal portion and a second barrier metal film formed on the second metal portion.

5. The semiconductor device according to claim 1, further comprising a semiconductor substrate including a diffusion region which is provided in a surface layer of the semiconductor substrate as the first conductive layer.

6. A method of fabricating a semiconductor device comprising:
forming a first insulating layer on a first conductive layer, the first insulating layer having an upper surface, the first conductive layer including an upper part;
forming a first hole which is adjacent to the upper part of the first conductive layer and extends through the first insulating layer, the first hole having an upper opening;
depositing a second conductive layer on the first insulating layer formed with the first hole so that the upper opening of the first hole is constricted by the second conductive layer, and simultaneously forming the second conductive layer along an inner surface of the first hole while a space is defined in the first hole;
planarizing the second conductive layer until the upper surface of the first insulating layer is reached;
forming a second insulating layer on the second conductive layer and the first insulating layer;
forming a second hole in the second insulating layer and simultaneously, removing an upper part of the second conductive layer so that the constricted upper opening of the first hole is enlarged; and
burying a third conductive layer inside the second conductive layer through the upper opening of the second hole.

7. The method according to claim 6, wherein the lower part of the hole is formed into a barreled shape.

8. The method according to claim 6, wherein in the step of forming the second conductive layer, the second conductive layer is formed so as to close the upper opening of the first hole.

9. A method of fabricating a semiconductor device comprising:
forming a first insulating layer on a first conductive layer, the first insulating layer having an upper surface, the first conductive layer including an upper part;
forming a first hole which is adjacent to the upper part of the first conductive layer and extends through the first insulating layer, the first hole having an upper opening;
forming a first barrier metal film along an inner surface of the first hole so that the upper opening of the first hole is constricted by the first barrier metal film;
burying a first metal layer inside the first barrier metal film in the first hole with void remaining while the first hole is further constricted by the first barrier metal film;
planarizing the first metal layer and the first barrier metal film until the upper surface of the first insulating layer is reached;
forming a second insulating layer on the planarized first metal layer, the first barrier metal film and the first insulating layer;
forming a second hole in the first metal layer and the second insulating layer on the first barrier metal layer, and simultaneously, removing the first metal layer and an upper part of the second barrier metal layer by an anisotropic etching process so that the upper opening of the constricted first hole is enlarged;
forming a second barrier metal layer along an inside of the first metal layer from an inner surface of the second hole formed in the second metal layer and the upper opening of the first hole; and
forming a second metal layer inside the second barrier metal layer.

10. The method according to claim 9, wherein the lower part of the hole is formed into a barreled shape.

11. The method according to claim 9, wherein in the step of burying the first metal layer, the first metal layer is buried inside the first barrier metal film so that the upper opening of the first hole is closed.

12. The method according to claim 10, wherein in the step of burying the first metal layer, the first metal layer is buried inside the first barrier metal film so that the upper opening of the first hole is closed.

13. The method according to claim 9, wherein:
the first conductive layer is comprised of silicon doped with impurities as a main material thereof;
in the step of forming the first barrier metal film, titanium (Ti) is formed by a sputtering process and subsequently, titanium nitride (TiN) is formed; and
in the step of removing the first barrier metal layer, titanium and titanium nitride are removed together with the second insulating layer.

14. The method according to claim 9, wherein the anisotropic etching process is carried out under a condition of use of a CF₄/O₂ mixed gas having a higher CF₄ gas ratio.

15. The method according to claim 9, wherein in the burying step, an atomic layer deposition (ALD) process is carried out and subsequently, a chemical vapor deposition (CVD) process is carried out.
